(19) United States
(12) Patent Application Publication
(10) Pub. No.: US 2024/0170205 A1
(43) Pub. Date: May 23, 2024

(54) MICRO-TRANSFORMER FOR ISOLATORS

(71) Applicant: RENESAS ELECTRONICS AMERICA INC., MILPITAS, CA (US)

(72) Inventors: Tetsuo SATO, San Jose, CA (US); Yukio Nomura, Tokyo (JP); James Edwin Vinson, Palm Bay, FL (US); Dev Alok Girdhar, Indialantic, FL (US)

(73) Assignee: RENESAS ELECTRONICS AMERICA INC., MILPITAS, CA (US)

(21) Appl. No.: 18/057,816

(22) Filed: Nov. 22, 2022

(51) Int. Cl. H01F 38/14; H01L 23/522; H02M 1/088; H02M 3/156

(52) U.S. Cl. CPC H01F 38/14; H01L 23/5227; H02M 1/088; H02M 3/156; H01F 2038/143; H01L 24/48; H01L 2224/48137

(57) ABSTRACT

Semiconductor devices for implementing an isolator are described. The semiconductor device can include a first chip including at least a first coil and a second coil magnetically coupled in a vertical alignment and isolated by a first insulator in the first chip. The semiconductor device can further include a second chip including at least a third coil and a fourth coil magnetically coupled in a vertical alignment and isolated by a second insulator in the second chip. The semiconductor device can include at least one bonding wire that connects the second coil in the first chip to the fourth coil in the second chip.

### BACKGROUND OF THE SPECIFICATION

The present disclosure relates in general to semiconductor devices. More specifically, the present disclosure relates to a micro-transformer including separated transmitting chip and receiving chip.

Isolation elements, or isolators, can be devices used for signal transfer between circuit blocks which have different reference voltage levels. Some examples of isolators can include photo-coupler, inductor-coupled isolator, capacitor-coupled isolator, or other types of isolators. In an aspect, an inductor-coupled isolator uses one coil to convert an electric signal to magnetism before getting another coil to convert the magnetism to an electric signal, thus ensuring isolation between two semiconductor devices. In an aspect, isolators that utilize a magnetic field can include micro-transformers having at least one transmitting coil and at least one receiving coil. Micro-transformers can be fabricated by IC backend process. Performance of isolators can be impacted by factors such as isolator size, noise immunity, operation speed and affinity of silicon integrated circuit (IC) process, or the like. For example, an isolation breakdown voltage of the micro-transformer can depend on the material of insulator and thickness between coils.

### SUMMARY

In one embodiment, a semiconductor device for implementing an isolator is generally described. The semiconductor device can include a first chip including at least a first coil and a second coil magnetically coupled in a vertical alignment and isolated by a first insulator in the first chip. The semiconductor device can further include a second chip including at least a third coil and a fourth coil magnetically coupled in a vertical alignment and isolated by a second insulator in the second chip. The semiconductor chip can further include at least one bonding wire that connects the second coil in the first chip to the fourth coil in the second chip.

In one embodiment, a semiconductor device is generally described. The semiconductor device can include a transmitter configured to output a transmission signal. The semiconductor device can further include a receiver. The semiconductor device can further include an isolator including a first chip including at least a first coil and a second coil magnetically coupled in a vertical alignment and isolated by a first insulator in the first chip. The isolator can further include a second chip including at least a third coil and a fourth coil magnetically coupled in a vertical alignment and isolated by a second insulator in the second chip. The isolator can further include at least one bonding wire that connects the second coil in the first chip to the fourth coil in the second chip. The isolator can be configured to receive the transmission signal from the transmitter and output the transmission signal to the receiver.

In one embodiment, A voltage regulator is generally described. The voltage regulator can include a controller configured to output a transmission signal. The voltage regulator can further include a power stage including a driver configured to drive a transistor. The voltage regulator can further include an isolator including a first chip including at least a first coil and a second coil magnetically coupled in a vertical alignment and isolated by a first insulator in the first chip. The isolator can further include a second chip including at least a third coil and a fourth coil magnetically coupled in a vertical alignment and isolated by a second insulator in the second chip. The isolator can further include at least one bonding wire that connects the second coil in the first chip to the fourth coil in the second chip. The isolator can be configured to receive the transmission signal from the controller and output the transmission signal to the driver.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1A is a diagram showing a conventional isolator integrated on the same chip as a transmitter.

FIG. 1B is a diagram showing another conventional isolator integrated on the same chip as a transmitter.

FIG. 2 is a diagram showing an embodiment of a micro-transformer for isolators in accordance with the present disclosure.

FIG. 3 is a diagram showing an example of a cross section of a micro-transformer for isolators in one embodiment.

FIG. 4 is a diagram showing another embodiment of a micro-transformer for isolators in accordance with the present disclosure.

FIG. 5 is a diagram showing an example environment that can validate a performance of a micro-transformer for isolators in one embodiment.

FIG. 6 is a diagram showing example performance of the micro-transformer for isolators under the environment of FIG. 5 in one embodiment.

FIG. 7 is a diagram showing an example application of a micro-transformer for isolators in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

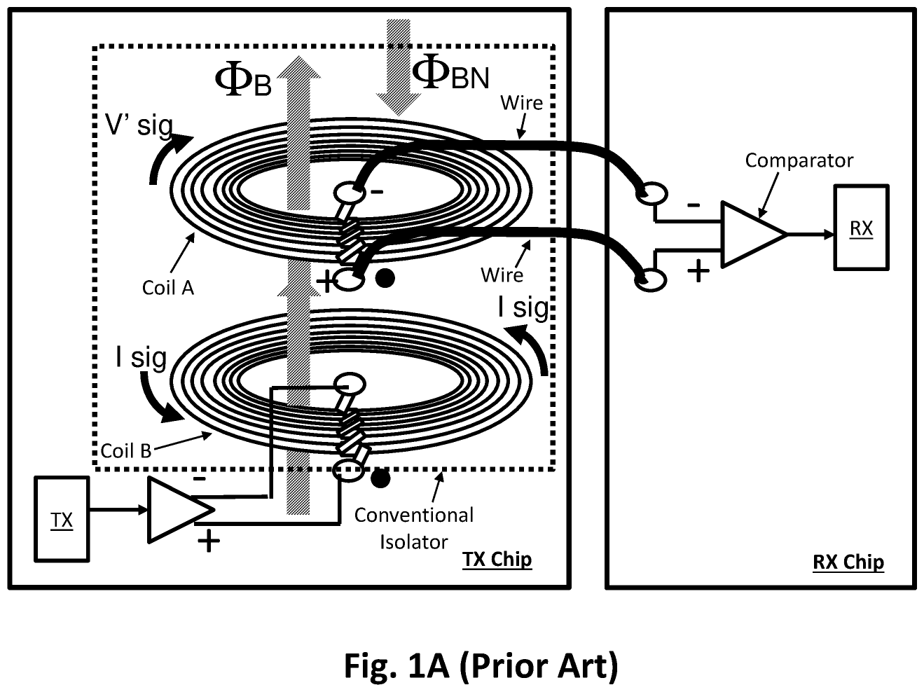

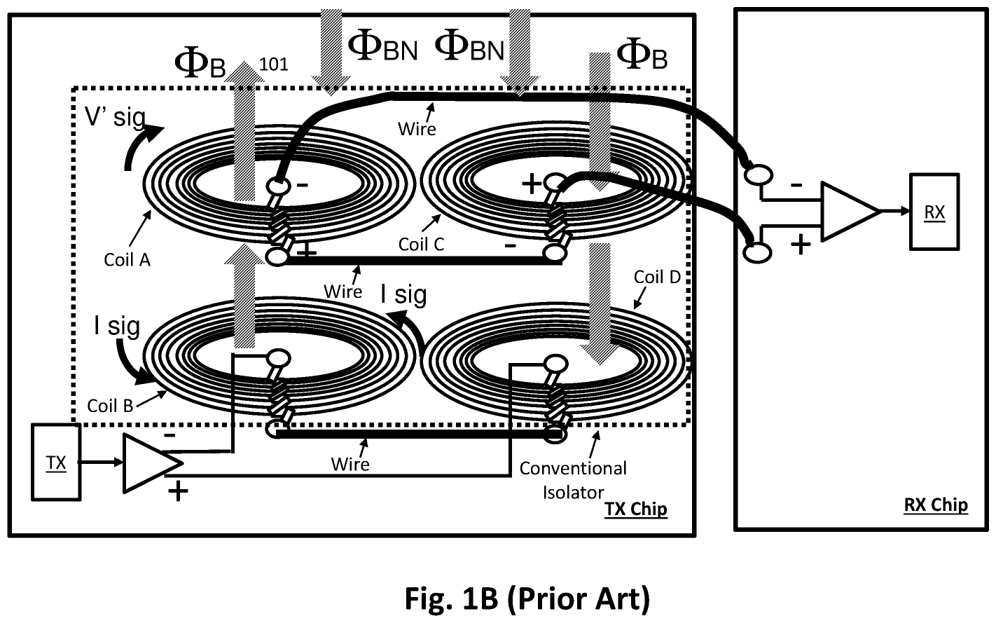

FIG. 1A is a diagram showing a conventional isolator integrated on the same chip as a transmitter. In an aspect shown in FIG. 1A, a conventional isolator can be integrated with a transmitter TX on a transmitter chip (TX Chip). The conventional isolator can include a coil labeled as Coil A, and another coil labeled as Coil B. Coil A and Coil B can be vertically aligned with one another on the TX Chip, where Coil A can be fabricated on a top layer of TX Chip and Coil B can be fabricated on a bottom layer of TX Chip. An insulator can be situated between Coil A and Coil B to isolate Coil A and Coil B. A set of wires can connect Coil A to a comparator fabricated on a receiver chip (RX Chip). In another example conventional configuration, the conventional isolator shown in FIG. 1A can be integrated in the RX Chip instead of the TX Chip. In this case, a comparator can be connected to bottom layer coil B and the TX chip transmitter can drive the top layer coil A.

Coil A and Coil B can be positioned within a specific vertical distance (e.g., defined by a thickness of an insulator between Coil A and Coil B) such that they can be inductively coupled to form a transformer. When a signal is transmitted from transmitter TX to Coil B, current can flow through coil B, thus creating a magnetic field Φ_{B}. Due to the inductive coupling between Coil A and Coil B, magnetic field Φ_{B} can induce voltage V′sig on coil A as an output signal, to the comparator in the RX Chip. A noise voltage ΔVn can be created by external magnetic fields Φ_{BN} that is different from Φ_{B}. When the noise voltage ΔVn is applied on Coil A, error can be inserted into the output signal being sent to the comparator of RX Chip.

FIG. 1B is a diagram showing another conventional isolator integrated on the same chip as a transmitter. In an aspect shown in FIG. 1B, a conventional isolator having four coils can be integrated with a transmitter TX on a transmitter chip (TX Chip). The conventional isolator in FIG. 1B can include four coils labeled as Coil A, Coil B, Coil C and Coil D. Coil A and Coil C can be fabricated on a top layer of the TX Chip and can be arranged to form a shape resembling the number “8”. Coil B and Coil D can be fabricated on a bottom layer of the TX Chip and can be arranged to form a shape resembling the number “8”. Coil A and Coil B can be vertically aligned with one another, and Coil C and Coil D can be vertically aligned with one another. An insulator can be situated between Coil A and Coil B to isolate Coil A and Coil B, and between Coil C and Coil D to isolate Coil C and Coil D. A set of wires can connect Coil B to Coil D, and at least one wire can connect Coil A to Coil C. Coil A and Coil C can be connected to a comparator fabricated on a receiver chip (RX Chip). In another example conventional configuration, the conventional isolator shown in FIG. 1B can be integrated in the RX Chip instead of the TX Chip.

Coil A and Coil B can be positioned within a specific vertical distance, and Coil C and Coil D can be positioned within the same specific vertical distance (e.g., defined by a thickness of an insulator between Coil A and Coil B and between Coil C and Coil D). Coil A and Coil C on the top layer, and Coil B and Coil D on the bottom layer, can be inductively coupled to form a transformer. When a signal is transmitted from transmitter TX to Coil B, current can flow through coil B. Due to the inductive coupling between Coil A and Coil B, the current of the signal being transmitted can create a magnetic field Φ_{B} having a direction from Coil B to Coil A. The magnetic field Φ_{B} can be applied to Coil C and Coil D and can have a direction from Coil C to Coil D. Coil A, Coil B, Coil C, Coil D can have the same size and shape. Coil A, Coil B, Coil C and Coil D can have the same winding direction. The coil current winding direction of Coil A and Coil B can be reverse or opposite from the coil current winding direction of Coil C and Coil D. The same sizes and the different coil current winding directions can cause the opposing magnetic field direction. The opposing directions of the magnetic field Φ_{B} can produce cascade gain voltage to top coils Coil A and Coil C, and current can be outputted from Coil A and Coil C, as an output signal, to the comparator in the RX Chip.

An external magnetic fields Φ_{BN}, that is different from Φ_{B}, can create a noise voltage ΔVn. When the noise voltage ΔVn is applied on Coil A and Coil C, error can be inserted into the output signal being sent to the comparator of RX Chip. The conventional isolator in FIG. 1B can cancel noise voltage ΔVn, but this conventional “8” shape configuration shown in FIG. 1B can take up relatively more board space and can limit flexibility in layout of the isolator and the TX Chip.

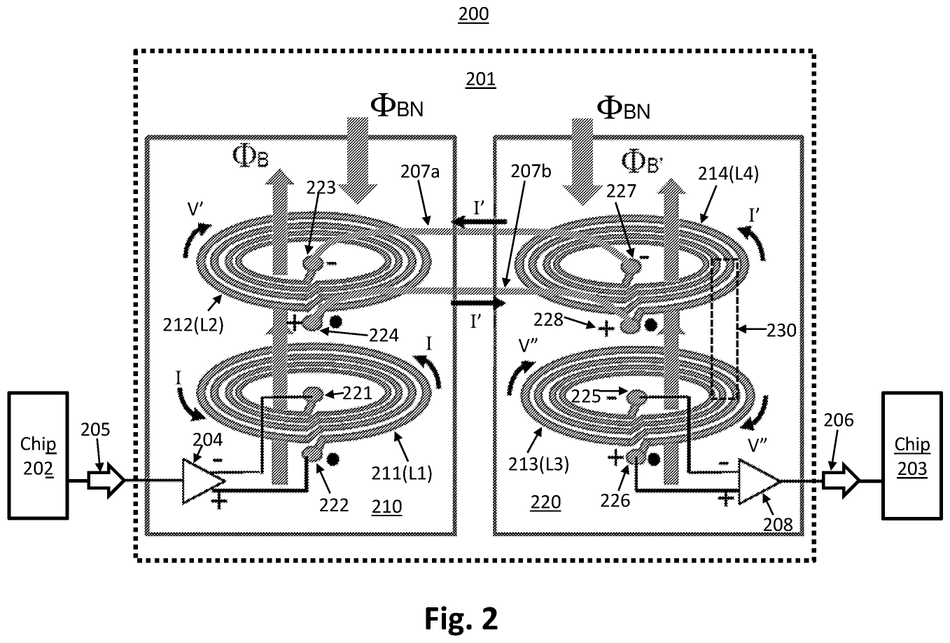

FIG. 2 is a diagram showing an embodiment of a micro-transformer for isolators in accordance with the present disclosure. A semiconductor package 200 can include a semiconductor chip or integrated circuit (IC) 202 (“chip 202”), a semiconductor chip or IC 203 (“chip 203”), and an isolator 201. Each one of chips 202, 203 can be configured as a transmitter chip (e.g., chip that outputs data or signals) or a receiver chip (e.g., chip that receives data or signals). In the example shown in FIG. 2, chip 202 can be configured as a transmitter chip and chip 203 can be configured as a receiver chip. In one embodiment, chip 202 can be a controller of a voltage regulator and chip 203 can be a power stage among a plurality of power stages in the voltage regulator. Chip 202 and chip 203 can have different reference voltage levels and isolator 201 can facilitate signal transfer between chip 202 and chip 203.

Isolator 201 can include a semiconductor chip or an integrated circuit (IC) 210 (“chip 210”) and a semiconductor chip or an IC 220 (“chip 220”). Chip 210 can include at least two coils, such as a coil 211 (or coil L1) and a coil 212 (or coil L2). Chip 220 can include at least two coils, such as a coil 213 (or coil L3) and a coil 214 (or coil L4). Each one of coils L1, L2, L3, L4 can be an individual inductor or winding of a conductive wire (e.g., composed of conductive materials such as copper). Further, coils L1, L2, L3, L4 can have the same diameter the same coil turn number, and the same winding direction.

Coil L2 can be fabricated on a top layer of chip 210 and coil L1 can be fabricated on a bottom layer of chip 210. Coil L1 and coil L2 can be vertically aligned with one another and an insulator (e.g., a core of chip 210) can be situated between coil L1 and coil L2 to isolate coil L1 and coil L2. Coil L4 can be fabricated on a top layer of chip 220 and coil L3 can be fabricated on a bottom layer of chip 220. Coil L3 and coil L4 can be vertically aligned with one another and an insulator (e.g., a core of chip 220) can be situated between coil L3 and coil L4 to isolate coil L3 and coil L4. Coil L2 and coil L4 on the top layer, and coil L1 and coil L3 on the bottom layer, can be inductively coupled to form a transformer.

Coil L2 in chip 210 and coil L4 in chip 220 can be electrically coupled by at least two bonding wires 207a, 207b. Coil L2 can include a center pad 223 and a terminal pad 224, and coil L4 can include a center pad 227 and a terminal pad 228. Center pads 223, 227 and terminal pads 224, 228 can be contacts formed by conductive materials. Bonding wire 207a can connect center pad 223 to center pad 227 and bonding wire 207b can connect terminal pad 224 to terminal pad 228.

When a signal encoding data, such as a transmission signal 205, is transmitted from chip 202 to coil L1, current I created by transmission signal 205 can flow through coil L1. In one embodiment, chip 202 can include an amplifier 204 configured to receive transmission signal 205 and output transmission signal 205 as a differential signal to coil L1. In one embodiment, amplifier 204 can be a differential amplifier. Due to the inductive coupling between coil L2 and coil L1, current I can excite coil L2, an excitation voltage V′ can be applied on coil L2 and a magnetic field Φ_{B} having a direction from coil L1 to coil L2 can be created. Excitation voltage V′ can create current I′ and coil L2 can output current I′ to coil L4. Current I′ flowing through coil L4 can excite coil L3, an excitation voltage V″ can be applied on coil L3 and a magnetic field Φ_{B}′ having a direction from coil L4 to coil L3 can be created. Current created by excitation voltage V″ can be outputted to chip 203. In one embodiment, chip 220 can include a comparator 208 configured to receive the current created by excitation voltage V″ from coil L3. In one embodiment, comparator 208 can be a NPN differential amplifier being implemented as a sensing comparator. Comparator 208 can output reception signal 206, where reception signal 206 can be different from transmission signal 205, such as having different waveform, amplitude and/or phase due to transform frequency pass band and noise in isolator 201.

In one embodiment, a thickness of coil L1 can be greater than a thickness of coil L2 and a thickness of coil L3 can be greater than a thickness of coil L4. Coil L1 and coil L3 can have the same thickness, and coil L2 and coil L4 can have the same thickness. A width (e.g., wire width) of coil L2 can be less than a width of coil L1 and a width of coil L4 can be less than a width of coil L3. Coil L1 and coil L3 can have the same width, and coil L2 and coil L4 can have the same width. Due to the greater width of coil L1, a spacing between wires of coil L1 can be less than a spacing between wires of coil L2. Coil L1 and coil L3 can have the same spacing. Due to the greater width of coil L3, a spacing between wires of coil L3 can be less than a spacing between wires of coil L4. Coil L2 and coil L4 can have the same spacing. Hence, the size, shape, dimensions, winding direction of chip 210 and chip 220 can be symmetric.

An external magnetic fields Φ_{BN}, that is different from Φ_{B} and Φ_{B}′, can be applied and thus creating noise voltage ΔVn. Due to the symmetry between chips 210, 220, coil L2 and coil L4 can excite the same voltage between center pad 223 and terminal pad 224, and between center pad 227 and terminal pad 228, and noise magnetic fields Φ_{BN} being applied to chips 210, 220 can have the same direction. The same excitation voltage can cancel the noise voltage ΔVn created by external magnetic fields Φ_{BN}.

In one embodiment, each one of chips 210, 220 can be a multi-layer semiconductor device. Breakdown voltages of chips 210, 220, and the overall breakdown voltage of isolator 201, can be dependent on the insulator material and backend process being used for fabricating the chips 210, 220. In an aspect, silicon dioxide (SiO₂) can be a material used as an insulator of a multi-layer backend process to fabricate isolators, such as isolator 201. Breakdown voltage of SiO2 can be approximately 450 volts per micrometer (V/μm), which causes a multi-layer device to achieve breakdown voltage of approximately 4 kilovolts (kV) to 4 kV. However, some applications may require a peak isolation voltage that is higher than the breakdown voltage.

Each one of chips 210, 220 can be a multi-layer semiconductor device fabricated by bipolar complementary metal-oxide-semiconductor (BiCMOS) process. The thickness of chips 210, 220 can define a breakdown voltage of isolator 201. If the BiCMOS process to fabricate chip 210 has a breakdown voltage of approximately four kilovolt peak (4 kVp), and chip 220 is fabricated using the same backend BiCMOS process, then based on the cascade configuration of chips 210, 220 (e.g., the electrical connection using bonding wires 207a, 270b), the total breakdown voltage of isolator 201 can be approximately eight kVp (8 kVp).

Therefore, the cascade connection of chips 210, 220 of isolator 201 can increase (e.g., double) a total breakdown voltage of isolator 201 when compared to conventional isolators such as the conventional isolator shown in FIG. 1A. Further, the symmetry of chips 210, 220 can improve noise cancellation when compared to conventional isolators such as the conventional isolators shown in FIG. 1A. Furthermore, the separation of coils into different chips 210, 220, and having the coils separated from transmitter and receiver (e.g., chips 202, 203), can provide flexibility in layout and sizing of the isolator 201 and/or semiconductor package 200. Therefore, isolator 201 can provide increased breakdown voltage and flexibility in layout and device sizing.

In an aspect, another factor of noise in an isolator can be dynamic common mode transient interference (D-CMTI). D-CMTI can refer to an immunity against high slew rate noise voltage caused by voltage being fed in between transmitter and receiver grounds of the micro-transformer (e.g., transformer in an isolator). This high slew rate noise voltage can transfer stray capacitance between coils of the isolator when coupled together. To improve D-CMTI, coupling needs to be reduced, and coil termination resistance and stray resistance can be minimized to reduce the coupling. The configuration of isolator 201 can reduce stray capacitance between coils when compared to conventional isolators (e.g., conventional isolators in FIG. 1A and FIG. 1B). The reduction of stray capacitance can improve (e.g., increase) D-CMTI level. For example, if the stray capacitance is halved then the D-CMTI can be doubled.

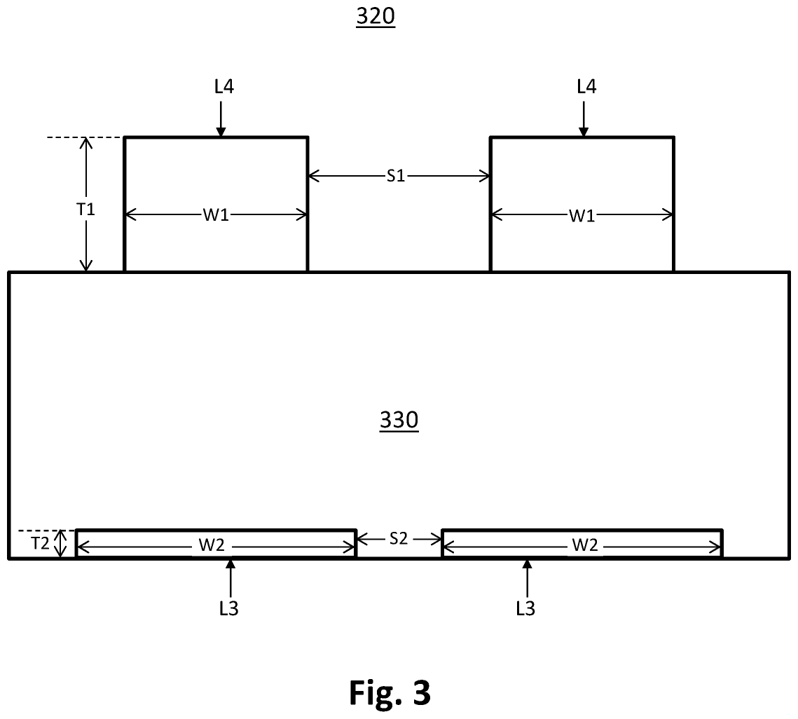

FIG. 3 is a diagram showing an example of a cross section of a micro-transformer for isolators in one embodiment. In FIG. 3, a cross section 230 of chip 220 in isolator 201 of FIG. 2 is shown. Coil L4 can be fabricated on a top-most layer of a core 330, and coil L3 can be fabricated on a bottom-most layer of core 330. Core 330 can be an insulator that isolates coil L4 and coil L3. In the embodiment shown in FIG. 3, coil L4 can have a width (e.g., wire width) of W1 and a spacing between wires of coil L4 can be S1. Coil L3 can have a width of W2 and a spacing between wires of coil L3 can be S2. W2 can be greater than W1 and S2 can be less than S1. Coil L4 can be thicker than coil L3. For example, coil L4 can have a thickness of T1 and coil L3 can have a thickness of T2, where T2 is less than T1. In an aspect, coil L4 (e.g., top coil) has a greater thickness than coil L3 (e.g., bottom coil) due to the top layer of a multilayer semiconductor process having a sheet resistance that is relatively lower than the sheet resistance bottom layer.

In the embodiment shown in FIG. 3, coils L4, L3 of chip 220 can be designed to have different width and spacing and the sum of the coil width and spacing are the same. For example, W1+S1 can be equivalent to W2+S2. Coil L3 can have a relatively lower stray resistance when compared to coils in conventional isolators, such as conventional isolators shown in FIG. 1A and FIG. 1B. Lower stray resistance at coil L3 can lead to lower termination resistance as well. Hence, designing the bottom coil (e.g., coil L3) to have different width and spacing (e.g., greater width and smaller spacing) can improve D-CMTI.

In one embodiment, a cross section of chip 210 in isolator 201 can be identical to cross section 230 shown in FIG. 3, where Coil L2 can be fabricated on a top-most layer of a core or insulator of chip 210, and coil L1 can be fabricated on a bottom-most layer of the core of chip 210. Coil L2 can have a width (e.g., wire width) of W1 and a spacing between wires of coil L2 can be S1. Coil L1 can have a width of W2 and a spacing between wires of coil L1 can be S2. W2 can be greater than W1 and S2 can be less than S1. Coil L2 can be thicker than coil L1. For example, coil L2 can have a thickness of T1 and coil L1 can have a thickness of T2, where T2 is less than T1. In an aspect, coil L2 (e.g., top coil) has a greater thickness than coil L1 (e.g., bottom coil) due to the multilayer process requirement.

In an aspect, electromagnetic interference (EMI) can emit from isolator 201 to other components (e.g., in semiconductor package 200). To reduce potential EMI emission, the current I driving coil L1 in chip 210 (see FIG. 2) can be minimized (e.g., to approximately 8 milliamperes (mA)).

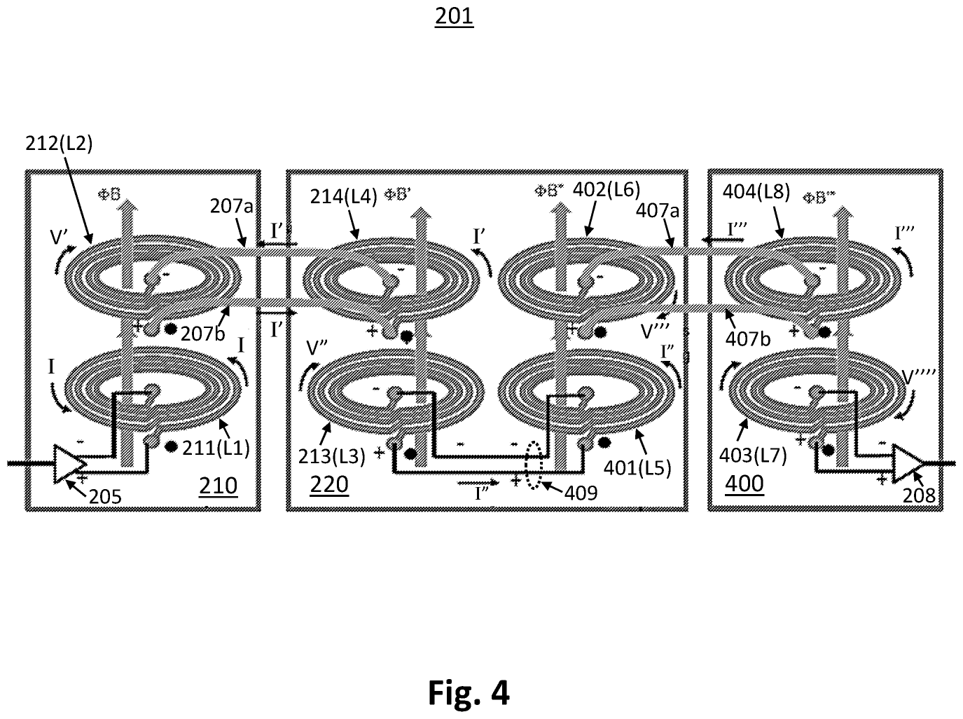

FIG. 4 is a diagram showing another embodiment of a micro-transformer for isolators in accordance with the present disclosure. An embodiment of isolator 201 (see FIG. 2) shown in FIG. 4 can be a double cascade transformer isolator. In one embodiment, each one of chips 210, 220 can have a respective breakdown voltage. A combined breakdown voltage of chips 210, 220 can be greater than each respective breakdown voltage of chips 210, 220. To further increase the breakdown voltage of isolator 201, additional chips similar to chips 210, 220 can be added to isolator 201. The embodiment of isolator 201 shown in FIG. 4 includes a chip 400 can be integrated in semiconductor package 200 of FIG. 2, and chip 400 can be connected to chip 220. In the embodiment shown in FIG. 4, chip 400 (instead of chip 220) can include comparator 208.

Additional coils can be added in chip 220 to allow chip 400 to be connected to, for example, chip 220 in isolator 201 to form a double cascade transformer isolator. In the embodiment shown in FIG. 4, chip 220 can further include a coil 401 (L5) and a coil 402 (L6) in order for chip 220 to connect to chip 400. Each one of coils L5, L6 can be an individual inductor or winding of a conductive wire (e.g., composed of conductive materials such as copper). Further, coils L5, L6 can have the same diameter the same coil turn number, and the same winding direction as coils L1, L2, L3, L4.

Coil L6 can be fabricated on a top layer of chip 220 and coil L5 can be fabricated on a bottom layer of chip 220. Coil L5 and coil L6 can be vertically aligned with one another and the insulator (e.g., the core of chip 220) can be situated between coil L5 and coil L6 to isolate coil L5 and coil L6. Coil L5 can be fabricated on the same layer as coil L3 and coil L6 can be fabricated on the same layer as coil L4. Coil L5 can have the same thickness as coil L3, and coil L6 can have the same thickness as coil L4. Coil L6 can have a greater thickness than coil L5 and coil L5 can have a greater wire width than coil L6. Coil L3 can be electrically connected to coil L5 in chip 220. In one embodiment, a pair of connection pattern 409 can connect a center pad (e.g., conductive contact) of coil L3 to a center pad of coil L5, and connect a terminal pad (e.g., conductive contact) of coil L3 to a terminal pad of coil L5.

Chip 400 can include a coil 403 (L7) and a coil 404 (L8). Each one of coils L7, L8 can be an individual inductor or winding of a conductive wire (e.g., composed of conductive materials such as copper). Coils L7, L8 can have the same diameter the same coil turn number, and the same winding direction as coils L1, L2, L3, L4, L5, L6. Coil L8 can be fabricated on a top layer of chip 400 and coil L7 can be fabricated on a bottom layer of chip 400. Coil L7 and coil L8 can be vertically aligned with one another and the insulator (e.g., the core of chip 400) can be situated between coil L7 and coil L8 to isolate coil L7 and coil L8. Coil L7 can have the same thickness as coils L1, L3, L5 and coil L8 can have the same thickness as coils L2, L4, L6. Coil L8 can have a greater thickness than coil L7 and coil L7 can have a greater wire width than coil L8. Coil L8 can be electrically connected to coil L6 in chip 220. A bonding wire 407a can connect a center pad (e.g., conductive contact) of coil L6 to a center pad of coil L8, and another bonding wire 407b can connect a terminal pad (e.g., conductive contact) of coil L6 to a terminal pad of coil L8.

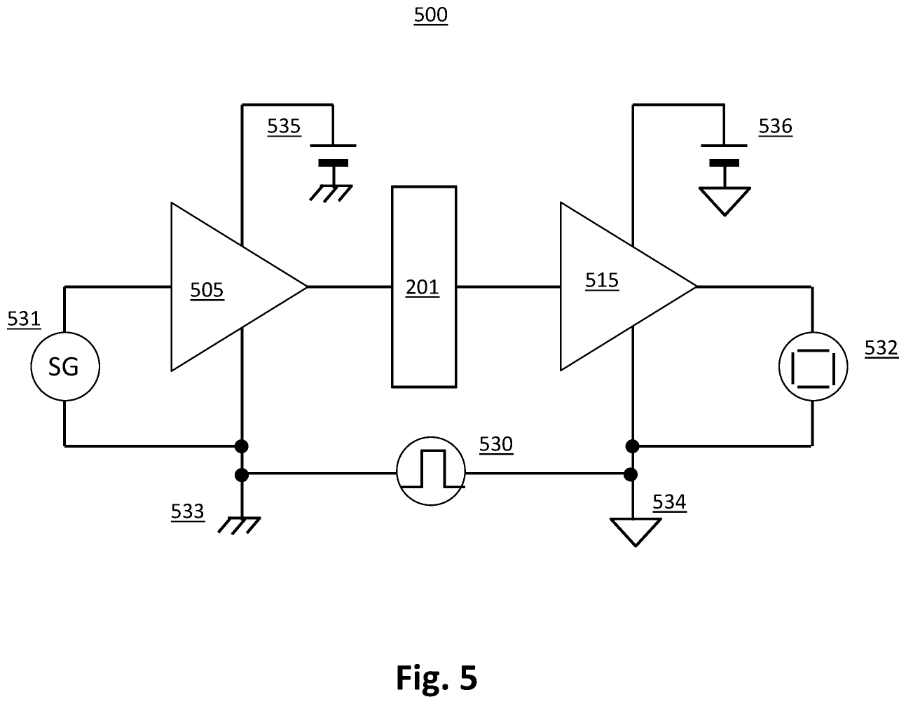

FIG. 5 is a diagram showing an example environment 500 that can evaluate a performance of a micro-transformer for isolators in one embodiment. Environment 500 can be a testing environment that can be implemented by a testing apparatus or equipment suitable to test and/or evaluate a performance of isolator 201. Environment 500 can include an input stage 505, an output stage 515, a voltage source 535 (e.g., Vcc voltage source) and a voltage source 536. Input stage 505 can simulate transmitter and output stage 515 can simulate a receiver. A test signal can be inputted to environment 500 at an input terminal 531 and output from an output terminal 532. Input terminal 531 can be connected to a signal generator that provides the test signal and output terminal 532 can be connected to an oscilloscope that can generate waveforms of signals measured at different nodes of environment 500.

In an aspect, a high CMTI or D-CMTI can protect a system or device using isolator 201 from undesired external voltages. Further, wide band gap devices (e.g., wide band gap transistors) such as silicon carbide (SiC) or gallium nitride (GaN) devices may need high D-CMTI performance isolators. To evaluate D-CMTI performance or high slew rate blocking performance of isolator 201, a high slew rate voltage source 530 can be inserted between a reference ground node 533 and a reference ground node 534. Reference ground node 533 and reference ground node 534 can be isolated from one another. A voltage slew rate level of voltage source 530 can be, for example, 100 to 200 kilovolts per microsecond (kV/μsec). Voltage source 530 can simulate undesired external voltages, such as surge voltage created by thunder, ignition noise, or the like. The simulation of high slew rate voltage using voltage source 530 can evaluate the D-CMTI performance of isolator 201, such as evaluating a capability of isolator 201 to block the high slew rate voltage created by voltage source 530 (e.g., minimize an impact of the high slew rate voltage on the test signal being transferred from input terminal 531 to output terminal 532).

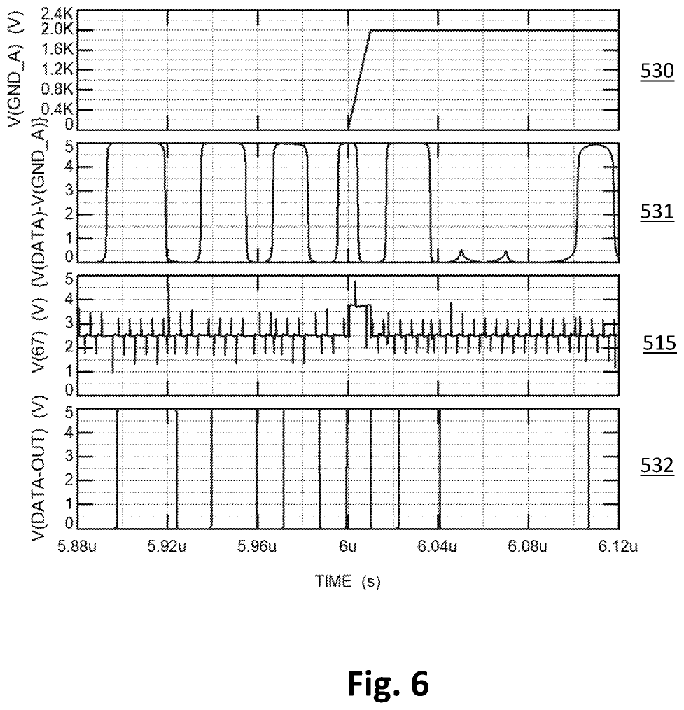

FIG. 6 is a diagram showing example performance of the micro-transformer for isolators under the environment of FIG. 5 in one embodiment. FIG. 6 shows waveforms of a signal created by voltage source 530 (see FIG. 5), an input signal (e.g., test signal) at input terminal 531, output of isolator 201 in FIG. 5 (e.g., to output stage 515), and an output signal from output terminal 532. The input signal at input terminal can be a pulse width modulation (PWM) signal. The output of isolator 201 can be a digital modulation waveform of the input PWM signal at input terminal 531. When the signal created by voltage source 530 goes HIGH (e.g., from 0V to approximately 2 kV), the output of isolator 201 can produce distortion signals (e.g., as indicated by the fluctuating signals in FIG. 6) but the voltage level remains within an acceptable range of 2.5±2.0V (e.g., 0.5V˜4.5V). Even though voltage source 530 introduces an external voltage, the output signal from output terminal 532 resembles the input PWM signal at input terminal 531, with probable delays. Thus, isolator 201 can reproduce the input signal with minimal error.

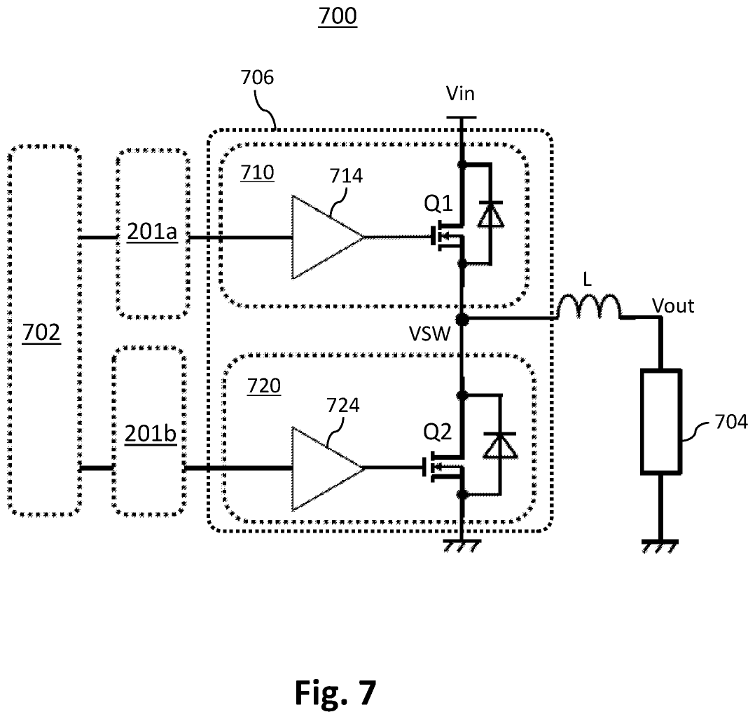

FIG. 7 is a diagram showing an example application of micro-transformer for isolators in one embodiment. In an example shown in FIG. 7, an apparatus 700 can be a power device such as a half-bridge buck converter, and apparatus 700 can convert relatively high input voltage into relatively low voltage. Apparatus 700 can include a controller 702 and at least one voltage regulators or power stages, such as a power stage 706. In one embodiment, apparatus 700 can be implemented by a semiconductor device or package, where controller 702, isolator 201, and power stage 706 are distinct semiconductor ICs or discrete devices. Each power stage can include a pair of transistors, such as transistors Q1, Q2 of power stage 706 shown in FIG. 7. In one embodiment, at least one of transistors Q1, Q2 can be high breakdown and high switching speed transistors, such as SiC metal-oxide-semiconductor field-effect transistors (MOSFET). Power stage 706 can include a high-side portion 710 and a low-side portion 720. High-side portion 710 can include a high-side driver 714 and transistor Q1. Low-side portion 720 can include a low-side driver 724 and transistor Q2. Controller 702 can be configured to control power stage 706 using a pulse width modulation (PWM) signal to alternately switch transistors Q1, Q2 to convert an input voltage Vin into an output voltage Vout that can be provided to a load 704.

One or more isolators can be connected between controller 702 and power stage 706. In one embodiment, one isolator 201 can be connected between controller 702 and high-side driver 714 and another isolator 201 can be connected between controller 702 and low-side driver 724. Isolator 201 can be connected between controller 702 and drivers of power stage 706 to transfer signals from controller 702 to a connected driver to accommodate the different reference voltage levels between controller 702 and power stage 706. Controller 702 can be configured to control power stage 706 using a pulse width modulation (PWM) signal to alternately switch transistors Q1, Q2 to convert an input voltage Vin into an output voltage Vout that can be provided to a load 704.

In one example, the reference voltage of controller 702 can be 0V and the low-side portion 720 can also be 0V, but the high-side portion 710 can be a VSW node voltage. VSW node voltage can be switched from 0 to Vin with relatively high speed (e.g., if Q1 and Q2 are high switching speed transistors). Isolator 201 described herein can be implemented to accommodate high breakdown voltage devices and provide high D-CMTI. Wide band gap devices such as SiC MOSFETs may require relatively higher breakdown voltage and switching speed. The high side interface isolator 201a input reference voltage can be 0V and output reference voltage is VSW. VSW voltage can be switching from 0 to Vin with relatively high speed. If Q1, Q2 are SiC MOSFET devices, the switching slew rate can be 50˜100 kV/μsec. Thus, isolator 201a can provide high D-CMTI, such as more than 100 kV/μsec. Otherwise, the VSW switching signal will feed back to isolator input signal as noise and makes intermodulation PWM input signal.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The disclosed embodiments of the present invention have been presented for purposes of illustration and description but are not intended to be exhaustive or limited to the invention in the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A semiconductor device comprising:
a first chip including at least a first coil and a second coil magnetically coupled in a vertical alignment and isolated by a first insulator in the first chip;
a second chip including at least a third coil and a fourth coil magnetically coupled in a vertical alignment and isolated by a second insulator in the second chip; and
at least one bonding wire that connects the second coil in the first chip to the fourth coil in the second chip.

2. The semiconductor device of claim 1, wherein:
the first coil is fabricated on a bottom layer of the first insulator;
the second coil is fabricated on a top layer of the first insulator using top metal layer process;
the third coil is fabricated on a bottom layer of the second insulator; and
the fourth coil is fabricated on a top layer of the second insulator using top metal layer process.

3. The semiconductor device of claim 1, wherein:
each one of the first coil, the second coil, the third coil, and the fourth coil has a spiral shape; and
the first coil, the second coil, the third coil, and the fourth coil have the same diameter, the same coil turn number, and the same winding direction.

4. The semiconductor device of claim 1, wherein:
the second coil includes a first pad at the center of the second coil;
the second coil includes a second pad at a terminal of the second coil;
the fourth coil includes a third pad at the center of the fourth coil;
the fourth coil includes a fourth pad at a terminal of the fourth coil;
the at least one bonding wire include a first bonding wire that connects the first pad to the third pad; and
the at least one bonding wire include a second bonding wire that connects the second pad to the fourth pad.

5. The semiconductor device of claim 1, wherein the first chip and the second chip form a transformer that implements an isolator.

6. The semiconductor of claim 1, wherein:
a thickness of the second coil is greater than a thickness of the first coil;
a thickness of the fourth coil is greater than a thickness of the third coil;
a width of the first coil is greater than a width of the second coil; and
a width of the third coil is greater than a width of the fourth coil.

7. The semiconductor device of claim 1, wherein an output terminal of the third coil is connected to a NPN differential comparator.

8. The semiconductor device of claim 1, further comprising a third chip, wherein:
the second chip includes a fifth coil and a sixth coil magnetically coupled in a vertical alignment and isolated by the second insulator in the second chip;
the third coil is electrically connected to the fifth coil;
the third chip includes a seventh coil and an eighth coil magnetically coupled in a vertical alignment and isolated by a third insulator in the third chip; and
a bonding wire connects the sixth coil in the second chip to the eighth coil in the third chip.

9. The semiconductor device of claim 8, wherein the first chip, the second chip, and the third chip form a transformer that implements an isolator.

10. A semiconductor device comprising:
a transmitter configured to output a transmission signal;
a receiver;
an isolator including:
a first chip including at least a first coil and a second coil magnetically coupled in a vertical alignment and isolated by a first insulator in the first chip;
a second chip including at least a third coil and a fourth coil magnetically coupled in a vertical alignment and isolated by a second insulator in the second chip; and
at least one bonding wire that connects the second coil in the first chip to the fourth coil in the second chip;
wherein the isolator is configured to:
receive the transmission signal from the transmitter; and
output the transmission signal to the receiver.

11. The semiconductor device of claim 10, wherein the transmitter is a controller of a voltage regulator and the receiver is a driver of the voltage regulator.

12. The semiconductor device of claim 10, wherein:
the first coil is fabricated on a bottom layer of the first insulator;
the second coil is fabricated on a top layer of the first insulator using top metal layer process;
the third coil is fabricated on a bottom layer of the second insulator; and
the fourth coil is fabricated on a top layer of the second insulator using top metal layer process.

13. The semiconductor device of claim 10, wherein:
each one of the first coil, the second coil, the third coil, and the fourth coil has a spiral shape;
the first coil, the second coil, the third coil, and the fourth coil have the same diameter;
the first coil, the second coil, the third coil, and the fourth coil have the same coil turn number; and
the first coil, the second coil, the third coil, and the fourth coil have the same winding direction.

14. The semiconductor device of claim 10, wherein:
the second coil includes a first pad at the center of the second coil;
the second coil includes a second pad at a terminal of the second coil;
the fourth coil includes a third pad at the center of the fourth coil;
the fourth coil includes a fourth pad at a terminal of the fourth coil;
the at least one bonding wire include a first bonding wire that connects the first pad to the third pad; and
the at least one bonding wire include a second bonding wire that connects the second pad to the fourth pad.

15. The semiconductor of claim 10, wherein:
a thickness of the second coil is greater than a thickness of the first coil;
a thickness of the fourth coil is greater than a thickness of the third coil;
a width of the first coil is greater than a width of the second coil; and
a width of the third coil is greater than a width of the fourth coil.

16. The semiconductor device of claim 10, wherein an output terminal of the third coil is connected to a NPN differential comparator.

17. The semiconductor device of claim 10, wherein:
the isolator further includes a third chip;
the second chip includes a fifth coil and a sixth coil magnetically coupled in a vertical alignment and isolated by the second insulator in the second chip;
the second coil is electrically connected to the fourth coil;
the third coil is electrically connected to the fifth coil;
the third chip includes a seventh coil and an eighth coil magnetically coupled in a vertical alignment and isolated by a third insulator in the third chip; and
a bonding wire connects the sixth coil in the second chip to the eighth coil in the third chip.

18. A voltage regulator comprising:
a controller configured to output a transmission signal;
a power stage including a driver configured to drive a transistor;
an isolator including:
a first chip including at least a first coil and a second coil magnetically coupled in a vertical alignment and isolated by a first insulator in the first chip;
a second chip including at least a third coil and a fourth coil magnetically coupled in a vertical alignment and isolated by a second insulator in the second chip; and
at least one bonding wire that connects the second coil in the first chip to the fourth coil in the second chip;
wherein the isolator is configured to:
receive the transmission signal from the controller; and
output the transmission signal to the driver.

19. The voltage regulator of claim 18, wherein:
the first coil is fabricated on a bottom layer of the first insulator;
the second coil is fabricated on a top layer of the first insulator using top metal layer process;
the third coil is fabricated on a bottom layer of the second insulator;
the fourth coil is fabricated on a top layer of the second insulator using top metal layer process;
the second coil includes a first pad at the center of the second coil;
the second coil includes a second pad at a terminal of the second coil;
the fourth coil includes a third pad at the center of the fourth coil;
the fourth coil includes a fourth pad at a terminal of the fourth coil;
the at least one bonding wire include a first bonding wire that connects the first pad to the third pad; and
the at least one bonding wire include a second bonding wire that connects the second pad to the fourth pad.

20. The voltage regulator of claim 18, wherein:
each one of the first coil, the second coil, the third coil, and the fourth coil has a spiral shape;
the first coil, the second coil, the third coil, and the fourth coil have the same diameter;
the first coil, the second coil, the third coil, and the fourth coil have the same coil turn number;
the first coil, the second coil, the third coil, and the fourth coil have the same winding direction;
a thickness of the second coil is greater than a thickness of the first coil;
a thickness of the fourth coil is greater than a thickness of the third coil;
a width of the first coil is greater than a width of the second coil; and
a width of the third coil is greater than a width of the fourth coil.
